(19) United States
(12) Patent Application Publication
(10) Pub. No.: US 2026/0176756 A1
(43) Pub. Date: Jun. 25, 2026

(54) METHOD AND SYSTEM FOR DEPOSITING LAYER COMPRISING BORON

(71) Applicant: ASM IP Holding B.V., Almere (NL)

(72) Inventors: João Ricardo Antunes Afonso, Tokyo (JP); Hideaki Fukuda, Tokyo (JP); Gaurav Pathak, Chandler, AZ (US); Mikko Tapani Ruoho, Nurmijärvi (FI); Viljami Pore, Helsinki (FI); Charles Dezelah, Helsinki (FI)

(21) Appl. No.: 19/422,884

(22) Filed: Dec. 17, 2025

Related U.S. Application Data
(60) Provisional application No. 63/736,841, filed on Dec. 20, 2024.

(51) Int. Cl. C23C 16/455; C23C 16/36; H10P 14/43; H10W 20/00

(52) U.S. Cl. CPC C23C 16/45531; C23C 16/36; C23C 16/45542; C23C 16/45553; H10P 14/43; H10W 20/032

(57) ABSTRACT

Methods for forming a layer comprising boron carbon nitride on a substrate by a plasma enhanced atomic layer deposition (PEALD) process are provided. The methods comprise executing a plurality of deposition cycles. A deposition cycle comprises a boron halide precursor pulse that comprises exposing the substrate to a boron precursor and a carbon-containing precursor pulse that comprises exposing the substrate to a carbon-containing precursor. A deposition cycle further comprises a plasma pulse that comprises exposing the substrate to a plasma treatment. The plasma treatment comprises generating a plasma.

### CROSS-REFERENCE TO RELATED APPLICATIONS

This application claims priority to U.S. Provisional Patent Application Ser. No. 63/736,841 filed Dec. 20, 2024 and titled METHOD AND SYSTEM FOR DEPOSITING LAYER COMPRISING BORON, the disclosure of which is hereby incorporated by reference in its entirety.

### FIELD OF INVENTION

The present disclosure generally relates to methods to the field of semiconductor processing methods and systems. In particular, methods and systems that can be used for depositing boron-consisting layers, such as boron carbon nitride (BCN) layers, by a cyclical deposition process.

### BACKGROUND OF THE DISCLOSURE

The down-scaling of semiconductor devices has resulted in improvements in the speed and density of integrated circuits. However, the miniaturization of devices is limited by increased resistance of interconnects and capacitance delay. To overcome this, interconnect materials having low relative dielectric constants (κ-values), that have low wet etch rate ratios (WERR) relative to other commonly-used materials, that serve as metal diffusion barriers, and that are thermally, chemically, and mechanically stable, are desirable. This has been difficult to obtain with materials such as low-κ SiCO that generally exhibit poor thermo-mechanical properties.

Any discussion, including discussion of problems and solutions, set forth in this section has been included in this disclosure solely for the purpose of providing a context for the present disclosure. Such discussion should not be taken as an admission that any or all of the information was known at the time the invention was made or otherwise constitutes prior art.

### SUMMARY OF THE DISCLOSURE

This summary is provided to introduce a selection of concepts in a simplified form. These concepts are described in further detail in the detailed description of example embodiments of the disclosure below. This summary is not intended to identify key features or essential features of the claimed subject matter, nor is it intended to be used to limit the scope of the claimed subject matter.

Various embodiments of the present disclosure relate to methods of depositing a layer comprising boron, carbon and nitrogen, to structures and devices formed using such methods, and to apparatus for performing the methods and/or for forming the structures and/or devices. The layers may be used for variety of applications, including etch stop layers, low-k layers, back-end-of-line dielectrics, capping layers, spacers, liners, and others.

Described herein is a method for forming a layer comprising boron, carbon and nitrogen on a surface of a substrate. The method comprises providing a substrate into a reaction chamber; and executing a plurality of deposition cycles. A deposition cycle comprises providing a boron halide precursor in vapor phase in the reaction chamber; providing a carbon-containing precursor in vapor phase in the reaction chamber; and providing a first reactive species generated from a plasma produced from a reactant gas into the reaction chamber. Thereby forming a layer comprising boron, carbon and nitrogen on a surface of a substrate.

In some embodiments, the boron halide precursor comprises a molecule selected from the list consisting of boron triiodide, boron tribromide, boron trichloride, diboron tetrachloride, borontrifluoride, boron monofluoride, boron tetrafluoride and diboron tetrafluoride.

In some embodiments, the boron halide precursor comprises boron tribromide.

In some embodiments, the carbon-containing precursor is selected from the group consisting of hydrocarbon, aryl halide, allyl halide, vinyl halide, propargyl halide, alkyl halide, alkyl, organohalosilane and alkylborane. In some embodiments the hydrocarbon is selected from the group consisting of alkane, alkene, alkyne, arene, cyclopentadiene and dicyclopentadiene. In some embodiments, the alkyne comprises terminal alkyne. In some embodiments, the carbon-containing precursor comprises alkylborane. In some embodiments, the alkylborane comprises trialkylborane. In some embodiments, the trialkylborane comprises at least one ethyl group.

In some embodiments, the carbon-containing precursor comprises triethylborane.

In some embodiments, the carbon-containing precursor comprises bromobis(dimethylamino) borane, tris(dimethylamino) borane and diiododimethylsilane.

In some embodiments, the method further comprises providing a second reactive species generated from a plasma produced from a reactant gas into the reaction chamber performed after providing the boron halide precursor into the reaction chamber.

In some embodiments, the method further comprises a purge step after providing the boron halide precursor into the reaction chamber.

In some embodiments, wherein the method further comprises a purge step after providing the carbon-containing precursor into the reaction chamber.

In some embodiments, wherein the method further comprises a purge step after providing the first and/or second reactive species into the reaction chamber.

In some embodiments, the reactant gas comprises at least one of the compounds selected from the group consisting of: ammonia, nitrogen, hydrogen or noble gas. In some embodiments, the reactant gas comprises nitrogen.

In some embodiments, the plasma is a direct plasma. In some embodiments, the plasma is a remote plasma.

In one aspect of the disclosure, a method for forming a layer comprising boron, carbon and nitrogen on a surface of a substrate is disclosed. The method comprises providing a substrate into a reaction chamber; and executing a plurality of deposition cycles. A deposition cycle comprises providing a boron precursor in vapor phase in the reaction chamber; providing a silicon halide precursor in vapor phase in the reaction chamber; providing a reactive species generated from a plasma produced from a reactant gas into the reaction chamber. Thereby forming a layer comprising boron, carbon and nitrogen on a surface of a substrate.

In some embodiments, the boron precursor is selected from the group consisting of boron halide, alkyl borane, amino borane and borane adduct.

In some embodiments, the silicon halide precursor comprises silicon atom and halogen atom, wherein the halogen atom is selected from chlorine, iodine, bromine and fluorine.

In a further aspect a semiconductor processing apparatus is disclosed. The apparatus comprises a reaction chamber comprising a substrate support for supporting a substrate; a heater constructed and arranged to heat the substrate in the reaction chamber; a plasma module comprising a radio frequency power source constructed and arranged to generate a plasma; a reactant gas source in fluid communication with the plasma module; a boron halide precursor source in fluid connection with the reaction chamber via one or more precursor valves; a carbon-containing precursor source in fluid connection with the reaction chamber via one or more precursor valves; and, a controller operably connected to the plasma module and the one or more precursor valves, and provided with a non-transitory computer readable medium programmed to cause the semiconductor processing apparatus to execute a plurality of deposition cycles. The deposition cycle comprises providing a boron halide precursor in vapor phase in the reaction chamber; providing a carbon-containing precursor in vapor phase in the reaction chamber; and providing a reactive species generated from a plasma produced from a reactant gas into the reaction chamber.

In a further aspect a semiconductor processing apparatus is disclosed. The apparatus comprises a reaction chamber comprising a substrate support for supporting a substrate; a heater constructed and arranged to heat the substrate in the reaction chamber; a plasma module comprising a radio frequency power source constructed and arranged to generate a plasma; a reactant gas source in fluid communication with the plasma module; a boron precursor source in fluid connection with the reaction chamber via one or more precursor valves; a silicon halide precursor source in fluid connection with the reaction chamber via one or more precursor valves; and, a controller operably connected to the plasma module and the one or more precursor valves, and provided with a non-transitory computer readable medium programmed to cause the semiconductor processing apparatus to execute a plurality of deposition cycles. The deposition cycle comprises providing a boron precursor in vapor phase in the reaction chamber; providing a silicon halide precursor in vapor phase in the reaction chamber; and providing a reactive species generated from a plasma produced from a reactant gas into the reaction chamber.

These and other embodiments will become readily apparent to those skilled in the art from the following detailed description of certain embodiments having reference to the attached figures. The invention is not limited to any particular embodiments disclosed.

### BRIEF DESCRIPTION OF THE DRAWING FIGURES

A more complete understanding of the embodiments of the present disclosure may be derived by referring to the detailed description and claims when considered in connection with the following illustrative figures.

FIG. 1 shows a schematic representation of an embodiment of a system (100) as described herein.

FIG. 2 shows a schematic representation of another embodiment of a system (200) as described herein.

FIG. 3 shows a schematic representation of a plasma-enhanced atomic layer deposition (PEALD) apparatus suitable for depositing a structure and/or for performing a method in accordance with at least one embodiment of the present disclosure.

FIG. 4 shows a schematic representation of an embodiment of a method as described herein.

FIG. 5 shows a schematic representation of an embodiment of a method as described herein.

It will be appreciated that elements in the figures are illustrated for simplicity and clarity and have not necessarily been drawn to scale. For example, the dimensions of some of the elements in the figures may be exaggerated relative to other elements to help improve understanding of illustrated embodiments of the present disclosure.

### DETAILED DESCRIPTION OF EXEMPLARY EMBODIMENTS

Although certain embodiments and examples are disclosed below, it will be understood by those in the art that the invention extends beyond the specifically disclosed embodiments and/or uses of the invention and obvious modifications and equivalents thereof. Thus, it is intended that the scope of the invention disclosed should not be limited by the particular disclosed embodiments described below

As used herein, the term “substrate” may refer to any underlying material or materials, including any underlying material or materials that may be modified, or upon which, a device, a circuit, or a film may be formed. The “substrate” may be continuous or non-continuous; rigid or flexible; solid or porous; and combinations thereof. The substrate may be in any form, such as a powder, a plate, or a workpiece. Substrates in the form of a plate may include wafers in various shapes and sizes. Substrates may be made from semiconductor materials, including, for example, silicon, silicon germanium, silicon oxide, gallium arsenide, gallium nitride and silicon carbide.

As examples, a substrate in the form of a powder may have applications for pharmaceutical manufacturing. A porous substrate may comprise polymers. Examples of workpieces may include medical devices (for example, stents and syringes), jewelry, tooling devices, components for battery manufacturing (for example, anodes, cathodes, or separators) or components of photovoltaic cells, etc.

A continuous substrate may extend beyond the bounds of a process chamber where a deposition process occurs. In some processes, the continuous substrate may move through the process chamber such that the process continues until the end of the substrate is reached. A continuous substrate may be supplied from a continuous substrate feeding system to allow for manufacture and output of the continuous substrate in any appropriate form.

Non-limiting examples of a continuous substrate may include a sheet, a non-woven film, a roll, a foil, a web, a flexible material, a bundle of continuous filaments or fibers (for example, ceramic fibers or polymer fibers). Continuous substrates may also comprise carriers or sheets upon which non-continuous substrates are mounted.

In some embodiments of the disclosure, the substrate may comprise a patterned substrate including high aspect ratio features, such as, for example, trench structures, vertical gap features, horizontal gap features, and/or fin structures. For example, the substrate may comprise one or more substantially vertical gap features and/or one or more substantially horizontal gap features. The term “gap feature” may refer to an opening or cavity disposed between opposing inclined sidewalls or two protrusions extending vertically from the surface of the substrate or opposing inclined sidewalls of an indentation extending vertically into the surface of the substrate. Such a gap feature may be referred to as a “vertical gap feature.” In some embodiments, the vertical gap features may have an aspect ratio (height:width) which may be greater than 2:1, or greater than 5:1, or greater than 10:1, or greater than 25:1, or greater than 50:1, or even greater than 100:1, wherein “greater than” as used in this example refers to a greater distance in the height of the gap feature.

In this disclosure, “gas” can include material that is a gas at normal temperature and pressure (NTP), a vaporized solid and/or a vaporized liquid, and can be constituted by a single gas or a mixture of gases, depending on the context. A gas other than the process gas, i.e., a gas introduced without passing through a gas distribution assembly, other gas distribution device, or the like, can be used for, e.g., sealing the reaction space, and can include a seal gas, such as a rare gas. In some cases, the term “precursor” can refer to a compound that participates in the chemical reaction that produces another compound, and particularly to a compound that constitutes a film matrix or a main skeleton of a film; the term “reactant” can be used interchangeably with the term precursor. Exemplary gasses can include precursors and reactants.

As used herein, the term “comprising” indicates that certain features are included, but that it does not exclude the presence of other features, as long as they do not render the claim or embodiment unworkable. In some embodiments, the term “comprising” includes “consisting”. As used herein, the term “consisting” indicates that no further features are present in the apparatus/method/product apart from the ones following said wording. When the term “consisting” is used referring to a chemical compound or substance, it indicates that the chemical compound only contains the components which are listed.

In the specification, it will be understood that the term “on” or “over” may be used to describe a relative location relationship. Another element, film or layer may be directly on the mentioned layer, or another layer (an intermediate layer) or element may be intervened therebetween, or a layer may be disposed on a mentioned layer but not completely cover a surface of the mentioned layer. Therefore, unless the term “directly” is separately used, the term “on” or “over” will be construed to be a relative concept. Similarly to this, it will be understood the term “under”, “underlying”, or “below” will be construed to be relative concepts.

The term “substantially” as applied to a composition, a method, or a system generally refers to a proportion of a value, a property, a characteristic, or the like, or conversely a lack thereof, that is at least about 70%, at least about 80%, at least about 90%, at least about 95%, at least about 97%, at least about 98%, at least about 99%, at least about 99.5%, at least about 99.9%, or more, or any proportion between about 70% and about 100%. In some embodiments, the term “substantially” means a proportion of about 90%, about 95%, about 97%, about 98%, about 99%, about 99.5%, or about 99.9%.

The term “essentially” as applied to a composition, a method, or a system generally means that the additional components do not substantially modify the properties and/or function of the composition, the method, or the system.

As used herein, the term “film” and/or “layer” can refer to any continuous or non-continuous structure and material, such as material deposited by the methods disclosed herein. For example, a film and/or layer can include two-dimensional materials, three-dimensional materials, nanoparticles, partial or full molecular layers or partial or full atomic layers or clusters of atoms and/or molecules. A film or layer may partially or wholly consist of a plurality of dispersed atoms on a surface of a substrate and/or embedded in a substrate/and/or embedded in a device manufactured on that substrate. A film or layer may comprise material or a layer with pinholes and/or isolated islands. A film or layer may be at least partially continuous. A film or layer may be patterned, e.g. subdivided, and may be comprised in a plurality of semiconductor devices.

As used herein, a “structure” can be or include a substrate as described herein. Structures can include one or more layers overlying the substrate, such as one or more layers formed according to a method as described herein. Device portions and interconnects can be or include structures.

The term “deposition process” as used herein can refer to the introduction of precursors (and/or reactants) into a reaction chamber to deposit a layer over a substrate. “Cyclical deposition processes” are examples of “deposition processes”.

The term “cyclic deposition process” or “cyclical deposition process” can refer to the sequential exposure of a substrate to precursors (and/or reactants) into a reaction chamber, and exposure of a substrate to plasma generated species to deposit a layer over the substrate and includes processing techniques such as plasma-enhanced atomic layer deposition (PEALD).

The term “plasma-enhanced atomic layer deposition” can refer to a deposition process in which deposition cycles, typically a plurality of consecutive deposition cycles, are conducted in a process chamber.

Generally, for a PEALD processes, during each cycle, a precursor is introduced to a reaction chamber and is chemisorbed to a deposition surface (e.g., a substrate surface that can include a previously deposited material from a previous PEALD cycle or other material) and forming about a monolayer or sub-monolayer of material that does not readily react with additional precursor (i.e., a self-limiting reaction). Thereafter, the substrate is exposed to a plasma-generated species which can be generated using any plasma, such as a direct, indirect, or remote plasma. Plasmas can be generated capacitively, inductively, using microwave radiation, or through other means. The plasma-generated species converts the chemisorbed precursor to the desired material on the deposition surface. Purging steps can be utilized during one or more cycles, e.g., after each step or pulse of each cycle, to remove any excess precursor from the process chamber and/or remove any excess plasma-generated species and/or reaction byproducts from the reaction chamber.

As used herein, the term “purge” may refer to a procedure in which a purge gas is provided to a reaction chamber in between a precursor pulse and a plasma pulse. It shall be understood that during a purge, the substrate is not exposed to plasma-generated species. For example, when a direct plasma is used, the plasma can be turned off during a purge. For example, a purge, e.g. using a purge gas such as nitrogen or a noble gas, may be provided between a precursor pulse and a reactant pulse, thus avoiding or at least minimizing gas phase interactions between the precursor and the reactant. It shall be understood that a purge can be effected either in time or in space, or both. For example in the case of temporal purges, a purge step can be used e.g. in the temporal sequence of providing a first precursor to a reaction chamber, providing a purge gas to the reaction chamber, and providing a second precursor to the reaction chamber, wherein the substrate on which a layer is deposited does not move. For example in the case of spatial purges, a purge step can take the following form: moving a substrate from a first location to which a first precursor is continually supplied, through a purge gas curtain, to a second location to which a second precursor is continually supplied.

As used herein, a “precursor” includes a gas or a material that can become gaseous and that can be represented by a chemical formula that includes an element which may be incorporated during a deposition process as described herein.

Further, in this disclosure, any two numbers of a variable can constitute a workable range of the variable, and any ranges indicated may include or exclude the endpoints. Additionally, any values of variables indicated (regardless of whether they are indicated with “about” or not) may refer to precise values or approximate values and include equivalents, and may refer to average, median, representative, majority, or the like. Further, in this disclosure, the terms “including,” “constituted by” and “having” refer independently to “typically or broadly comprising,” “comprising,” “consisting essentially of,” or “consisting of” in some embodiments.

As used herein, “boron nitride” can be a material that can be represented by a chemical formula that includes boron and nitrogen. In some embodiments, boron nitride may not include significant proportions of elements than boron and nitride. In some embodiments, the boron nitride comprises BN. In some embodiments, the boron nitride may consist essentially of BN. In some embodiments, the boron nitride may consist of boron nitride. A layer consisting of boron nitride may include an acceptable amount of impurities, such as hydrogen, carbon, iodine, bromine and/or the like that may originate from one or more precursors used to deposit boron nitride.

As used herein, “boron carbonitride” can be a material that can be represented by a chemical formula that includes boron, carbon and nitrogen. In some embodiments, boron nitride may not include significant proportions of elements than boron, carbon and nitride. In some embodiments, the boron carbonitride comprises BCN. In some embodiments, the boron carbonitride may consist essentially of BCN. In some embodiments, the boron carbonitride may consist of boron carbonitride. A layer consisting of boron carbonitride may include an acceptable amount of impurities, such as hydrogen, silicon, iodine, bromine and/or the like that may originate from one or more precursors used to deposit boron carbonitride.

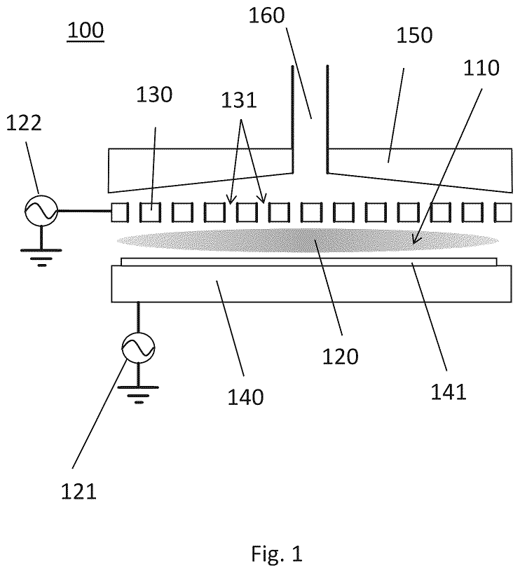

Now turning to the figures, FIG. 1 shows a schematic representation of an embodiment of a system (100) as described herein. The system (100) comprises a reaction chamber (110) in which a plasma (120) is generated. In particular, the plasma (120) is generated between a showerhead injector (130) and a substrate support (140). This is a direct plasma configuration employing a capacitively coupled plasma.

In the configuration shown, the system (100) comprises two alternating current (AC) power sources: a high frequency power source (121) and a low frequency power source (122). In the configuration shown, the high frequency power source (121) supplies radio frequency (RF) power to the showerhead injector, and the low frequency power source (122) supplies an alternating current signal to the substrate support (140). The radio frequency power can be provided, for example, at a frequency of 13.56 MHz or higher, e.g. at a frequency of at least 100 kHz to at most 50 MHz, or at a frequency of at least 50 MHz to at most 100 MHz, or at a frequency of at least 100 MHz to at most 200 MHz, or at a frequency of at least 200 MHz to at most 500 MHz, or at a frequency of at least 500 MHz to at most 1000 MHz, or at a frequency of at least 1000 MHz to at most 2000 MHz. The low frequency alternating current signal can be provided, for example, at a frequency of 2 MHz or lower, such as at a frequency of at least 100 kHz to at most 200 kHz, or at a frequency of at least 200 kHz to at most 500 kHz, or at a frequency of at least 500 kHz to at most 1000 kHz, or at a frequency of at least 1000 kHz to at most 2000 kHz.

Process gas comprising precursor, reactant, or both, is provided through a gas line (160) to a conical gas distributor (150). The process gas then passes through holes (131) in the showerhead injector (130) to the reaction chamber (110).

Whereas the high frequency power source (121) is shown as being electrically connected to the showerhead injector, and the low frequency power source (122) is shown as being electrically connected to the substrate support (140), other configurations are possible as well. For example, in some embodiments (not shown), both the high frequency power source and the low frequency power source can be electrically connected to the showerhead injector; or both the high frequency power source and the low frequency power source can be electrically connected to the substrate support; or the high frequency power source can be electrically connected to the substrate support, and the low frequency power source can be electrically connected to the showerhead injector.

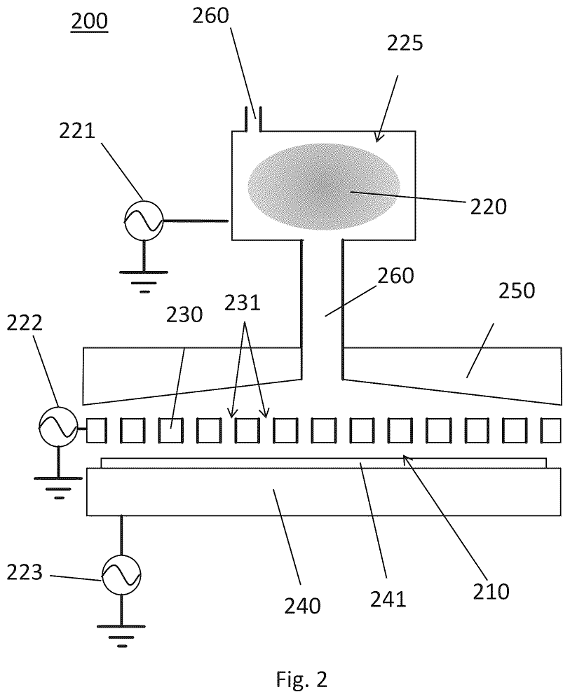

FIG. 2 shows a schematic representation of another embodiment of a system (200) as described herein. The configuration of FIG. 2 can be described as a remote plasma system. The system (200) comprises a reaction chamber (210) which is operationally connected to a remote plasma source (225) in which a plasma (220) is generated. Any sort of plasma source can be used as a remote plasma source (225), for example an inductively coupled plasma, a capacitively coupled plasma, or a microwave plasma.

In particular, active species are provided from the plasma source (225) to the reaction chamber (210) via an active species duct (260), to a conical distributor (250), through holes (231) in a shower plate injector (230), to the reaction chamber (210). Thus, active species can be provided to the reaction chamber in a uniform way.

In the configuration shown, the system (200) comprises three alternating current (AC) power sources: a high frequency power source (221) and two low frequency power sources (222,223): a first low frequency power source (222) and a second low frequency power source (223). In the configuration shown, the high frequency power source (221) supplies radio frequency (RF) power to the plasma generation space ceiling, the first low frequency power source (222) supplies an alternating current signal to the showerhead injector (230), and the second low frequency power source (223) supplies an alternating current signal to the substrate support (240). A substrate (241) is provided on the substrate support (240). The radio frequency power can be provided, for example, at a frequency of 13.56 MHz or higher. The low frequency alternating current signal of the first and second low frequency power sources (222,223) can be provided, for example, at a frequency of 2 MHz or lower.

In some embodiments (not shown), an additional high frequency power source can be electrically connected to the substrate support. Thus, a direct plasma can be generated in the reaction chamber.

Process gas comprising precursor, reactant, or both, is provided to the plasma source (225) by means of a gas line (260). Active species such as ions and radicals generated by the plasma (225) from the process gas are guided to the reaction chamber (210).

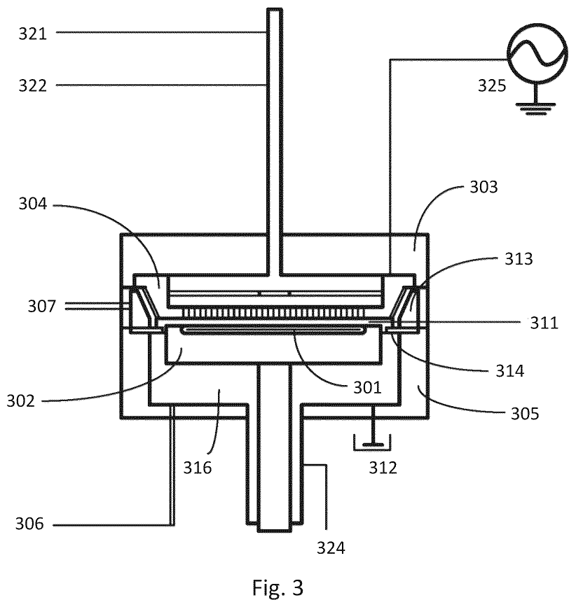

The presently provided methods may be executed in any suitable apparatus, including in an embodiment of a semiconductor processing system as shown in FIG. 3. FIG. 3 is a schematic view of a plasma-enhanced atomic layer deposition (PEALD) apparatus, usable in some embodiments of the present invention. In this figure, by providing a pair of electrically conductive flat-plate electrodes (302,304) in parallel and facing each other in the interior (311) (reaction zone) of a reaction chamber (303), applying RF power (e.g. at 13.56 MHz and/or 27 MHz) from a power source (325) to one side, and electrically grounding the other side (312), a plasma can be generated between the electrodes. Of course, there is no need for the semiconductor processing apparatus to generate a plasma during the steps when a precursor is provided to the reaction chamber, or during purges between subsequent processing steps, and no RF power need be applied to any one of the electrodes during those steps or purges. A temperature regulator may be provided in a lower stage (302), i.e. the lower electrode. A substrate (301) is placed thereon and its temperature is kept constant at a given temperature. The upper electrode (304) can serve as a shower plate as well, and various gasses such as a plasma gas, a reactant gas and/or a dilution gas, if any, as well as a precursor gas can be introduced into the reaction chamber (303) through a gas line (321) and a gas line (322), respectively, and through the shower plate (304). Additionally, in the reaction chamber (303), a circular duct (313) with an exhaust line (317) is provided, through which the gas in the interior (311) of the reaction chamber (303) is exhausted. Additionally, a transfer chamber (305) is disposed below the reaction chamber (303) and is provided with a gas seal line (324) to introduce seal gas into the interior (311) of the reaction chamber (303) via the interior (316) of the transfer chamber (305) wherein a separation plate (314) for separating the reaction zone and the transfer zone is provided.

Note that a gate valve through which a wafer may be transferred into or from the transfer chamber (305) is omitted from this figure. The transfer chamber is also provided with an exhaust line (306).

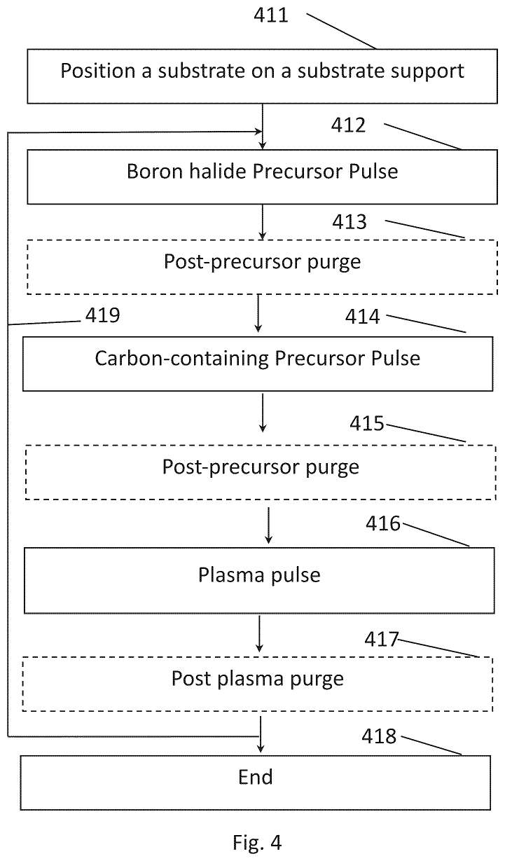

FIG. 4 shows a schematic representation of an embodiment of a method as described herein. The method comprises a step (411) of positioning a substrate on a substrate support in a reaction chamber. The reaction chamber used during step (411) can be or include a reaction chamber of a chemical vapor deposition reactor system configured to perform a deposition process. The deposition process may be a chemical vapor deposition process and/or a cyclical deposition process. The reaction chamber can be a standalone reaction chamber or part of a cluster tool. The reaction chamber may be a batch processing tool. In some embodiments, a flow-type reactor may be utilized. In some embodiments, a showerhead-type reactor may be utilized. In some embodiments, a space divided reactor may be utilized. In some embodiments, a high-volume manufacturing-capable single wafer reactor may be utilized. In other embodiments, a batch reactor comprising multiple substrates may be utilized. For embodiments in which a batch reactor is used, the number of substrates may be in the range of 10 to 200, or 50 to 150, or even 100 to 130. The reactor can be configured as a thermal reactor—with no plasma excitation apparatus. Alternatively, the reactor can include direct and/or remote plasma apparatus.

In some embodiments, if desired, the exposed surfaces of the substrate may be pretreated to provide reactive sites. In some embodiments, a separate pretreatment step is not required. In some embodiments, the substrate is pretreated to provide a desired surface termination, for example, by exposing the substrate surface to a pretreatment plasma.

In some embodiments of the disclosure, the substrate disposed within the reaction chamber may be heated to a desired deposition temperature for a subsequent deposition. For example, the substrate may be heated to a substrate temperature of less than approximately 600° C., less than approximately 500° C., or less than approximately 450° C., or less than approximately 400° C., or less than approximately 350° C., or less than approximately 300° C., or less than approximately 250° C., or even less than approximately 200° C. In some embodiments of the disclosure, the substrate temperature during step 102 may be greater than room temperature, between approximately 300° C. and approximately 600° C. or approximately 350° C. and approximately 550° C. or approximately 200° C. and approximately 450° C. The lower temperatures may be preferred for plasma-assisted processes, while the higher temperatures may be desired for thermal deposition processes. The temperature during steps (412) and/or (414) can also be within these ranges.

In addition to controlling the temperature of the substrate, the pressure in the reaction chamber may also be regulated to enable deposition of desired boron carbonitride. In some embodiments, a pressure can be controlled between about 0.5 Torr and about 50 Torr (e.g., for thermal processes) or about 1 Torr and about 20 Torr (e.g., for plasma-enhanced processes). The pressure during steps (412) and/or (414) can also be within these ranges.

Once the temperature of substrate has been set to the desired deposition temperature and pressure in the reaction chamber has been regulated as desired, the method may continue to comprise sequentially executing a plurality of deposition cycles (419). A deposition cycle (419) comprises a boron halide precursor pulse (412), a carbon-containing precursor pulse (414) and a plasma pulse (416). The term “pulse” can be understood to comprise feeding a precursor into the reaction chamber for a predetermined amount of time. Unless otherwise noted, the term “pulse” does not restrict the length or duration of the pulse and a pulse may be any length of time.

The boron halide precursor pulse (412) comprises exposing the substrate to a boron halide precursor (412). In some embodiments of the disclosure, the vapor phase boron halide precursor comprises boron and at least one halogen selected from iodine, fluorine, chlorine and bromine. In some embodiments, the boron halide precursor comprises a molecule selected from the list consisting of boron triiodide, boron tribromide, boron trichloride, diboron tetrachloride, borontrifluoride, boron monofluoride, boron tetrafluoride and diboron tetrafluoride. In accordance with some embodiments of the disclosure, the boron halide precursor consists of boron and one or more of iodine and bromine. For example, the boron halide precursor can be or include boron triiodide (BI₃) and/or boron tribromide (BBr₃). In some embodiments, the boron halide precursor comprises boron tribromide. In one embodiment the pulse time may be between 0.01 to 2 seconds, or between 0.3 to 1 seconds. In addition, during the contacting of the substrate with the boron halide precursor, the flow rate of the boron halide precursor may be less than 20 slm, or less than 10 slm, or less than 7 slm, or less than 5 slm, or even less than 3 slm. In addition, during the contacting of substrate with the boron halide precursor, the flow rate of the boron halide precursor may range from about 0.05 to 10 slm, from about 0.1 to 7 slm, or from about 0.1 to about 5 slm. In some embodiments, when the boron halide precursor is fed into the reaction chamber, nitrogen is used as a carrier gas.

The carbon precursor pulse (414) comprises exposing the substrate to a carbon precursor (414). In some embodiments of the disclosure, the carbon-containing precursor is selected from the group consisting of hydrocarbon, aryl halide, allyl halide, vinyl halide, propargyl halide, alkyl halide, alkyl, organohalosilane and alkylborane. In some embodiments the hydrocarbon is selected from the group consisting of alkane, alkene, alkyne, arene, cyclopentadiene and dicyclopentadiene. In some embodiments, the alkyne comprises terminal alkyne. In some embodiments, the alkylborane comprises trialkylborane. In some embodiments, the trialkylborane comprises at least one ethyl group. In some embodiments, the carbon-containing precursor comprises triethylborane. In some embodiment, the carbon-containing precursor comprises a molecule selected from bromobis(dimethylamino) borane, tris(dimethylamino) borane and diiododimethylsilane. In one embodiment the pulse time may be between 0.01 to 2 seconds, or between 0.3 to 1 seconds. In addition, during the contacting of the substrate with the carbon-containing precursor, the flow rate of the carbon-containing precursor may be less than 20 slm, or less than 10 slm, or less than 7 slm, or less than 5 slm, or even less than 3 slm. In addition, during the contacting of substrate with the carbon-containing precursor, the flow rate of the carbon-containing precursor may range from about 0.05 to 10 slm, from about 0.1 to 7 slm, or from about 0.1 to about 5 slm. In some embodiments, when the carbon-containing precursor is fed into the reaction chamber, nitrogen is used as a carrier gas.

The plasma pulse (416) comprises providing a reactive species generated from a plasma produced from a reactant gas into the reaction chamber. In some embodiments, the reactant gas comprises nitrogen. In some embodiments the reactant gas comprises at least one of the compounds selected from the group consisting of ammonia, nitrogen, hydrogen and noble gas. In one embodiment the pulse time may be between 0 to 60 seconds, or between 1 to 50 seconds, or between 10 to 40 seconds. For example, a nitrogen-based plasma may be generated by applying RF power from about 10 W to about 2000 W, or from about 50 W to about 1000 W, or from about 100 W to about 500 W. In some embodiments, the plasma may be generated in-situ (e.g. direct plasma), while in other embodiments, the plasma may be generated remotely. In some embodiments, a showerhead reactor may be utilized and plasma may be generated between a susceptor (on top of which the substrate is located) and a showerhead plate.

It shall be understood that a boron halide precursor pulse (412), a carbon-containing precursor pulse (414) and a plasma pulse (416) do not overlap, or do not substantially overlap. In other words, the boron halide precursor pulse (412), the carbon-containing precursor pulse (414) and the plasma pulse (416) are carried out sequentially. In some embodiments, the precursor pulses (412, 414) and the plasma pulses (416) are separated by purges (413, 415, 417). In other words, in some embodiments, the boron halide precursor pulse (412) is followed by a post-precursor purge (413) and the carbon-containing precursor pulse (414) is followed by a post-precursor purge (415), and the plasma pulse (516) is followed by a post-plasma purge (417). The purge time for the post-precursor purges (413, 415) may be between 0.1 to 10 seconds, or between 0.1 to 5 seconds, such as about 0.5 seconds, such as about 1 second or about 2 second. The purge time for the post-plasma purge may be between 0.05 to 5 seconds, or between 0.05 to 2 seconds, such as about 0.1 seconds, or about 0.5 seconds. Purging can be done, for example, by exposing the substrate to a noble gas or an inert gas or without gas flowing. Exemplary noble gasses include He, Ne, Ar, Xe, and Kr. Exemplary inert gases include N₂. In the embodiment where the purge is done without gas flowing the system is pumped down.

Thus, a layer comprising boron carbon nitride is formed on the substrate. The process steps can be repeated until a desired thickness of the target material is reached. In some embodiments, the method comprises from at least 1 cycle to at most 100 cycles, or from at least 2 cycles to at most 80 cycles, or from at least 3 cycles to at most 70 cycles, or from at least 4 cycles to at most 60 cycles, or from at least 5 cycles to at most 50 cycles, or from at least 10 cycles to at most 40 cycles, or from at least 20 cycles to at most 30 cycles. In some embodiments, the method comprises at most 100 cycles, or at most 90 cycles, or at most 80 cycles, or at most 70 cycles, or at most 60 cycles, or at most 50 cycles, or at most 40 cycles, or at most 30 cycles, or at most 20 cycles, or at most 10 cycles, or at most 5 cycles, or at most 4 cycles, or at most 3 cycles, or at most 2 cycles, or a single cycle. When a desired amount of layer comprising boron carbon and nitrogen has been formed on the substrate, the method ends (418).

While the PEALD cycle is generally referred to herein as beginning with the boron halide precursor pulse (412), it is contemplated that in other embodiments the cycle may begin with the reactive species phase. One of skill in the art will recognize that the first precursor phase generally reacts with the termination left by the last phase in the previous cycle. Thus, while no reactant may be previously absorbed on the substrate surface or present in the reaction chamber if the reactive species is the first phase in the PEALD cycle, in subsequent cycles the reactive species phase will effectively follow the boron phase. In some embodiments, one or more different PEALD cycles are provided in the deposition process.

In some embodiments, the process may include a second plasma pulse (not shown in figure). This second plasma pulse would take place after the boron halide precursor pulse. The second plasma pulse comprises providing a second reactive species generated from a plasma produced from a reactant gas into the reaction chamber performed after providing the boron halide precursor into the reaction chamber. Otherwise, the second plasma pulse is similar to the plasma pulse (416), also referred to as the first plasma pulse.

In some embodiments, the growth rate of the boron carbonitride film per unit deposition cycle may be greater than 0.02 nanometers per cycle, or greater than 0.05 nanometers per cycle, or greater than 0.1 nanometer per cycle. In some embodiments, the growth rate of the boron carbonitride film per unit deposition cycle may be between 0.01 to 0.2 nanometer per cycle, such as 0.02 to 0.14 at a deposition temperature of greater than 250° C.

In some embodiments, the boron carbonitride may be deposited to a thickness from about 0.5 nanometers to about 10 nanometers, or from about 1 nanometers to about 10 nanometers, or from about 1 nanometers to about 5 nanometers. These thicknesses may be achieved in feature sizes (width) below about 100 nanometers, or below about 50 nanometers, or below about 30 nanometers, or below about 20 nanometers, or even below about 10 nanometers.

In some embodiments of the disclosure, the boron carbonitride may be deposited on a three-dimensional structure, e.g., a non-planar substrate comprising high aspect ratio features. In some embodiments, the step coverage of the boron carbonitride film may be equal to or greater than about 50%, or greater than about 60%, or greater than about 70%, or greater than about 80%, or greater than about 90%, or greater than about 95%, or greater than about 98%, or greater than about 99%, or greater in structures having aspect ratios (height/width) of more than about 2, more than about 5, more than about 10, more than about 25, more than about 50, or even more than about 100.

As noted above, in accordance with some examples of the disclosure, the deposition process can be a thermal deposition process. In these cases, the deposition process does not include use of a plasma to form activated species for use in the deposition process. For example, the deposition process may not comprise formation or use of plasma, may not comprise formation or use of excited species, and/or may not comprise formation or use of radicals. In the case of thermal cyclical deposition processes, a duration of the step of providing precursor to the reaction chamber can be relatively long to allow the precursor to react with another precursor or a derivative thereof. For example, the duration can be greater than or equal to 5 seconds or greater than or equal to 10 seconds or between about 5 and 10 seconds.

In other cases, as noted herein, a plasma can be used to excite one or more precursors and/or one or more inert gases.

In some embodiments, the resulting layer may have a refractive index of at least 1.4 to at most 2.8, for example at least 1.7 to at most 2.2, such as between 1.75 to 2.0. In some embodiments, the resulting layer may have dielectric constant of less than 3, such as less than 2.5, for example less than 2.

In some embodiments, the boron carbonitride deposited according to a method disclosed herein may have superior etch resistance to comparable boron carbonitride films deposited by prior processes. For example, the ratio of a wet etch rate of the boron carbonitride films deposited by a method of the disclosure relative to a wet etch rate of thermal silicon oxide (WERR) in dilute hydrofluoric acid (1:100) may be less than 1.0, or less than 0.5, or less than 0.4, or less than 0.2, or less than 0.1, or between approximately 0 and approximately 0.1.

In some embodiments of the disclosure, the resulting film may be deposited on a three-dimensional structure, e.g., a non-planar substrate comprising high aspect ratio features. In some embodiments, the step coverage of the boron nitride film may be equal to or greater than about 50%, or greater than about 60%, or greater than about 70%, or greater than about 80%, or greater than about 90%, or greater than about 95%, or greater than about 98%, or greater than about 99%, or greater in structures having aspect ratios (height/width) of more than about 2, more than about 5, more than about 10, more than about 25, more than about 50, or even more than about 100.

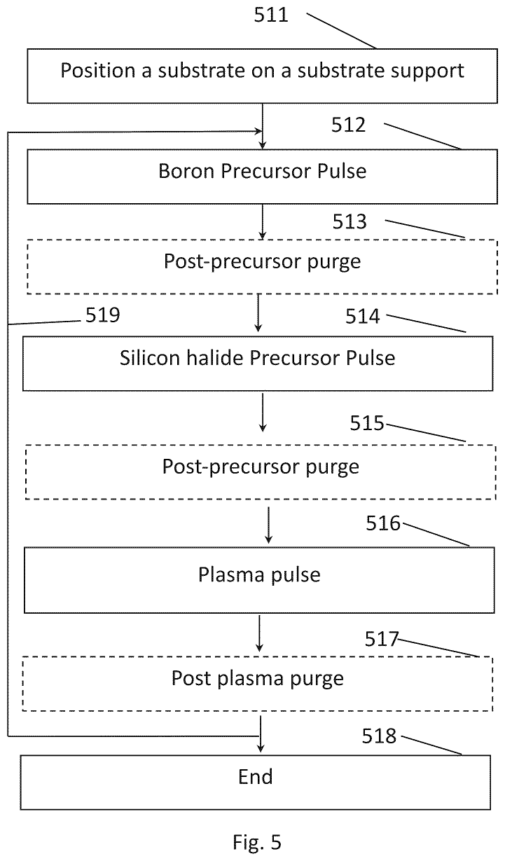

FIG. 5 shows a schematic representation of an embodiment of a method as described herein. The method comprises a step (511) of positioning a substrate on a substrate support in a reaction chamber. The reaction chamber can be similar to the one used in accordance with FIG. 4. Also, the temperatures and pressures can be similar to the ones used in accordance with FIG. 4.

Then, the method comprises sequentially executing a plurality of deposition cycles (519). A deposition cycle (519) comprises a boron precursor pulse (512), a silicon halide precursor pulse (514) and a plasma pulse (516). The boron precursor pulse (512) comprises exposing the substrate to a boron precursor (512). In some embodiments, the boron precursor is selected from the group consisting of boron halide, alkyl borane, amino borane and borane adduct.

In some embodiments the boron halide comprises a molecule selected from the list consisting of boron triiodide, boron tribromide, boron trichloride, diboron tetrachloride, boron trifluoride, boron monofluoride, boron tetrafluoride and diboron tetrafluoride.

In some embodiments, the alkyl borane comprises a trialkylborane, for example, triethylborane.

In some embodiments, aminoborane has the formula BXₙ(NRR′)ₘ where n+m=3 and n can equal 0, 1, or 2. The R and R′ are independently selected from H, C1-C8 alkyl, Si(Me)₃, Si(Et)₃ and SiH₃. X is selected independently from group consisting of H, C1-C10 alkyl, phenyl, F, Cl, Br, or I. In some embodiments, the C1-C8 alkyl is selected from methyl, ethyl and isopropopyl. In some embodiments, the NRR′ group comprises a heterocycle that comprises nitrogen and carbon atoms. In some embodiments aminoborane is selected from, H₃NBH₃ BCl₂NⁱPr₂ BCl₂N (SiMe₃)₂, B(NMe₂)₃, B₂ (NMe₂)₄, BBr (NMe₂)₂ and BCl(NMe₂)₂.

In some embodiments, borane adduct comprises the formula BX₃L, where X is H, C1-C10 alkyl, phenyl, F, Cl, Br, or I and where L is a neutral ligand comprising a nitrogen atom that forms a dative bond to the boron atom. In some embodiments, the neutral ligand is an alkylamine, dialkylamine or trialkylamine. In some embodiments, the alkyl group contains 1-10 carbon atoms. In some embodiments, the alkyl groups are independently selected from Me, Et, Pr, iPr, Bu, iBu, sBu, or tBu. In some embodiments, the neutral ligand comprises a cyclic amine, such as pyridine, piperidine, pyrrole, pyrrolidine, imidazole, pyrazole, triazole, or triazine (and C1-C5 alkyl versions thereof). In some embodiments, the borane adduct is selected from the list of boranetriethylamine, trimethylamineborane, trichloro(N,N-dimethylmethanamine) boron, pyridine-borane, pyridine-trifluoroborane tert-Butylamine borane, and 2-picoline-borane.

In one embodiment the pulse time may be between 0.01 to 2 seconds, or between 0.3 to 1 seconds. In addition, during the contacting of the substrate with the boron precursor, the flow rate of the boron precursor may be less than 20 slm, or less than 10 slm, or less than 7 slm, or less than 5 slm, or even less than 3 slm. In addition, during the contacting of substrate with the boron precursor, the flow rate of the boron precursor may range from about 0.05 to 10 slm, from about 0.1 to 7 slm, or from about 0.1 to about 5 slm. In some embodiments, when the boron precursor is fed into the reaction chamber, nitrogen is used as a carrier gas.

The silicon halide precursor pulse (514) comprises exposing the substrate to a silicon halide precursor (514). In some embodiments, the silicon halide precursor comprises silicon atom and halogen atom, wherein the halogen atom is selected from chlorine, iodine, bromine and fluorine. In some embodiments, the silicon halide is selected from the group consisting of diiodosilane, diiododimethylsilane, Iodosilane, triiodosilane, silicon tetraiodide, dichlorosilane, trichlorosilane, methyltrichlorosilane, dimethyldichlorosilane, trimethylchlorosilane, silicon tetrabromide, dibromosilane, tribromosilane, dimethyldibromosilane, silicon tetrachloride, hexachlorodisilane, octachlorotrisilane, bis(trichlorosilyl) methane, 1,1-bis(trichlorosilyl) ethane, 1,2-bis(trichlorosilyl) ethane. In one embodiment the pulse time may be between 0.01 to 2 seconds, or between 0.3 to 1 seconds. In addition, during the contacting of the substrate with the silicon halide precursor, the flow rate of the boron precursor may be less than 20 slm, or less than 10 slm, or less than 7 slm, or less than 5 slm, or even less than 3 slm. In addition, during the contacting of substrate with the silicon halide precursor, the flow rate of the silicon halide precursor may range from about 0.05 to 10 slm, from about 0.1 to 7 slm, or from about 0.1 to about 5 slm. In some embodiments, when the silicon halide precursor is fed into the reaction chamber, nitrogen is used as a carrier gas.

The plasma pulse (516) comprises exposing the substrate to plasma-generated active species. The plasma pulse step (516) can be similar to plasma pulse step (416) as explained in accordance with FIG. 4. In one embodiment the pulse time may be between 0 to 10 seconds, or between 1 to 5 seconds. In some embodiments, the plasma may be generated in-situ (e.g. direct plasma), while in other embodiments, the plasma may be generated remotely. In some embodiments, a showerhead reactor may be utilized and plasma may be generated between a susceptor (on top of which the substrate is located) and a showerhead plate.

It shall be understood that a boron precursor pulse (512), a silicon halide precursor pulse (514) and a plasma pulse (516) do not overlap, or do not substantially overlap. In other words, the boron precursor pulse (512), the silicon halide precursor pulse (514) and the plasma pulse (516) are carried out sequentially. In some embodiments, the precursor pulses (512, 514) and the plasma pulses (516) are separated by purges (513, 515, 517). In other words, in some embodiments, the boron precursor pulse (512) is followed by a post-precursor purge (513) and the silicon halide precursor pulse (514) is followed by a post-precursor purge (515), and the plasma pulse (516) is followed by a post-plasma purge (517). The purge time for the post-precursor purges (513, 515) may be between 0.1 to 10 seconds, or between 0.1 to 5 seconds, such as about 0.5 seconds, such as about 1 second or about 2 second. The purge time for the post-plasma purge may be between 0.05 to 5 seconds, or between 0.05 to 2 seconds, such as about 0.1 seconds, or about 0.5 seconds. Purging can be done, for example, by exposing the substrate to a noble gas or an inert gas or without gas flowing. Exemplary noble gasses include He, Ne, Ar, Xe, and Kr. Exemplary inert gases include N₂. In the embodiment where the purge is done without gas flowing the system is pumped down.

Thus, a layer comprising boron carbon nitride is formed on the substrate. In some embodiments, the layer may additionally comprise silicon. In some embodiments, the layer does not comprise carbon. In some embodiments, the layer comprises silicon boron nitride. The process steps can be repeated until a desired thickness of the target material is reached. In some embodiments, the method comprises from at least 1 cycle to at most 100 cycles, or from at least 2 cycles to at most 80 cycles, or from at least 3 cycles to at most 70 cycles, or from at least 4 cycles to at most 60 cycles, or from at least 5 cycles to at most 50 cycles, or from at least 10 cycles to at most 40 cycles, or from at least 20 cycles to at most 30 cycles. In some embodiments, the method comprises at most 100 cycles, or at most 90 cycles, or at most 80 cycles, or at most 70 cycles, or at most 60 cycles, or at most 50 cycles, or at most 40 cycles, or at most 30 cycles, or at most 20 cycles, or at most 10 cycles, or at most 5 cycles, or at most 4 cycles, or at most 3 cycles, or at most 2 cycles, or a single cycle. When a desired amount of layer comprising boron carbon and nitrogen has been formed on the substrate, the method ends (518).

While the PEALD cycle is generally referred to herein as beginning with the boron precursor pulse (512), it is contemplated that in other embodiments the cycle may begin with the reactive species phase. One of skill in the art will recognize that the first precursor phase generally reacts with the termination left by the last phase in the previous cycle. Thus, while no reactant may be previously absorbed on the substrate surface or present in the reaction chamber if the reactive species is the first phase in the PEALD cycle, in subsequent cycles the reactive species phase will effectively follow the boron phase. In some embodiments, one or more different PEALD cycles are provided in the deposition process.

In some embodiments, the process may include a second plasma pulse (not shown in figure). This second plasma pulse would take place after the boron precursor pulse. The second plasma pulse comprises providing a second reactive species generated from a plasma produced from a reactant gas into the reaction chamber performed after providing the boron halide precursor into the reaction chamber. Otherwise, the second plasma pulse is similar to the plasma pulse (516), also referred to as the first plasma pulse.

In some embodiments, the growth rate of the boron carbonitride film per unit deposition cycle may be greater than 0.02 nanometers per cycle, or greater than 0.05 nanometers per cycle, or greater than 0.1 nanometer per cycle. In some embodiments, the growth rate of the boron carbonitride film per unit deposition cycle may be between 0.01 to 0.2 nanometer per cycle, such as 0.02 to 0.14 at a deposition temperature of greater than 250° C.

In some embodiments, the boron carbonitride may be deposited to a thickness from about 0.5 nanometers to about 20 nanometers, or from about 1 nanometers to about 10 nanometers, or from about 1 nanometers to about 5 nanometers. These thicknesses may be achieved in feature sizes (width) below about 100 nanometers, or below about 50 nanometers, or below about 30 nanometers, or below about 20 nanometers, or even below about 10 nanometers.

In some embodiments of the disclosure, the boron carbonitride may be deposited on a three-dimensional structure, e.g., a non-planar substrate comprising high aspect ratio features. In some embodiments, the step coverage of the boron carbonitride film may be equal to or greater than about 50%, or greater than about 60%, or greater than about 70%, or greater than about 80%, or greater than about 90%, or greater than about 95%, or greater than about 98%, or greater than about 99%, or greater in structures having aspect ratios (height/width) of more than about 2, more than about 5, more than about 10, more than about 25, more than about 50, or even more than about 100.

As noted above, in accordance with some examples of the disclosure, the deposition process can be a thermal deposition process. In these cases, the deposition process does not include use of a plasma to form activated species for use in the deposition process. For example, the deposition process may not comprise formation or use of plasma, may not comprise formation or use of excited species, and/or may not comprise formation or use of radicals. In the case of thermal cyclical deposition processes, a duration of the step of providing precursor to the reaction chamber can be relatively long to allow the precursor to react with another precursor or a derivative thereof. For example, the duration can be greater than or equal to 5 seconds or greater than or equal to 10 seconds or between about 5 and 10 seconds.

In other cases, as noted herein, a plasma can be used to excite one or more precursors and/or one or more inert gases.

In some embodiments, the resulting layer may have a refractive index of at least 1.4 to at most 2.8, for example at least 1.7 to at most 2.2, such as between 1.75 to 2.0. In some embodiments, the resulting layer may have dielectric constant of less than 3, such as less than 2.5, for example less than 2.

In some embodiments, the boron carbonitride deposited according to a method disclosed herein may have superior etch resistance to comparable boron carbonitride films deposited by prior processes. For example, the ratio of a wet etch rate of the boron carbonitride films deposited by a method of the disclosure relative to a wet etch rate of thermal silicon oxide (WERR) in dilute hydrofluoric acid (1:100) may be less than 1.0, or less than 0.5, or less than 0.4, or less than 0.2, or less than 0.1, or between approximately 0 and approximately 0.1.

In some embodiments of the disclosure, the resulting film may be deposited on a three-dimensional structure, e.g., a non-planar substrate comprising high aspect ratio features. In some embodiments, the step coverage of the boron nitride film may be equal to or greater than about 50%, or greater than about 60%, or greater than about 70%, or greater than about 80%, or greater than about 90%, or greater than about 95%, or greater than about 98%, or greater than about 99%, or greater in structures having aspect ratios (height/width) of more than about 2, more than about 5, more than about 10, more than about 25, more than about 50, or even more than about 100.

The illustrations presented herein are not meant to be actual views of any particular material, structure, or device, but are merely idealized representations that are used to describe embodiments of the disclosure.

The particular implementations shown and described are illustrative of the invention and its best mode and are not intended to otherwise limit the scope of the aspects and implementations in any way. Indeed, for the sake of brevity, conventional manufacturing, connection, preparation, and other functional aspects of the system may not be described in detail. Furthermore, the connecting lines shown in the various figures are intended to represent exemplary functional relationships and/or physical couplings between the various elements. Many alternative or additional functional relationship or physical connections may be present in the practical system, and/or may be absent in some embodiments.

It is to be understood that the configurations and/or approaches described herein are exemplary in nature, and that these specific embodiments or examples are not to be considered in a limiting sense, because numerous variations are possible. The specific routines or methods described herein may represent one or more of any number of processing strategies. Thus, the various acts illustrated may be performed in the sequence illustrated, in other sequences, or omitted in some cases.

The subject matter of the present disclosure includes all novel and nonobvious combinations and subcombinations of the various processes, systems, and configurations, and other features, functions, acts, and/or properties disclosed herein, as well as any and all equivalents thereof.

1. A method for forming a layer comprising boron, carbon and nitrogen on a surface of a substrate, the method comprising:
providing a substrate into a reaction chamber; and
executing a plurality of deposition cycles, a deposition cycle comprising:
providing a boron halide precursor in vapor phase in the reaction chamber;
providing a carbon-containing precursor in vapor phase in the reaction chamber;
providing a first reactive species generated from a plasma produced from a reactant gas into the reaction chamber,
thereby forming a layer comprising boron, carbon and nitrogen on a surface of a substrate.

2. The method according to claim 1, wherein the boron halide precursor comprises a molecule selected from the list consisting of boron triiodide, boron tribromide, boron trichloride, diboron tetrachloride, boron monofluoride, boron trifluoride and diboron tetrafluoride.

3. The method according to claim 2, wherein the boron halide precursor comprises boron tribromide.

4. The method according to claim 1, wherein the carbon-containing precursor is selected from the group consisting of hydrocarbon, aryl halide, allyl halide, vinyl halide, propargyl halide, alkyl halide, organohalosilane and alkylborane.

5. The method according to claim 4, wherein the carbon-containing precursor comprises alkylborane.

6. The method according to claim 5, wherein the alkylborane comprises trialkylborane.

7. The method according to claim 6, wherein the trialkylborane comprises at least one ethyl group.

8. The method according to claim 1, wherein the carbon-containing precursor comprises triethylborane.

9. The method according to claim 1, wherein the carbon-containing precursor comprises a molecule selected from bromobis(dimethylamino) borane, tris(dimethylamino) borane and diiododimethylsilane.

10. The method according to claim 1, wherein the method further comprises providing a second reactive species generated from a plasma produced from a reactant gas into the reaction chamber performed after providing the boron halide precursor into the reaction chamber.

11. The method according to claim 1, wherein the method further comprises a purge step after providing the boron halide precursor into the reaction chamber.

12. The method according to claim 1, wherein the method further comprises a purge step after providing the carbon-containing precursor into the reaction chamber.

13. The method according to claim 1, wherein the method further comprises a purge step after providing the first and/or second reactive species into the reaction chamber.

14. The method according to claim 1, wherein the reactant gas comprises at least one of the compounds selected from the group consisting of: ammonia, nitrogen, hydrogen and noble gas.

15. The method according to claim 1, wherein the reactant gas comprises nitrogen.

16. The method according to claim 1, wherein the plasma is a direct plasma.

17. The method according to claim 1, wherein the plasma is a remote plasma.

18. A method for forming a layer comprising boron, carbon and nitrogen on a surface of a substrate, the method comprising:
providing a substrate into a reaction chamber; and
executing a plurality of deposition cycles, a deposition cycle comprising:
providing a boron precursor in vapor phase in the reaction chamber;
providing a silicon halide precursor in vapor phase in the reaction chamber;
providing a reactive species generated from a plasma produced from a reactant gas into the reaction chamber,
thereby forming a layer comprising boron, carbon and nitrogen on a surface of a substrate.

19. The method according to claim 16, wherein the boron precursor is selected from the group consisting of boron halide, alkyl borane, amino borane and borane adduct.

20. The method according to claim 16, wherein the silicon halide precursor comprises silicon atom and halogen atom, wherein the halogen atom is selected from chlorine, iodine, bromine and fluorine.

21. A semiconductor processing apparatus comprising:
a reaction chamber comprising a substrate support for supporting a substrate;
a heater constructed and arranged to heat the substrate in the reaction chamber;
a plasma module comprising a radio frequency power source constructed and arranged to generate a plasma;
a reactant gas source in fluid communication with the plasma module;
a boron halide precursor source in fluid connection with the reaction chamber via one or more precursor valves;
a carbon-containing precursor source in fluid connection with the reaction chamber via one or more precursor valves; and,
a controller operably connected to the plasma module and the one or more precursor valves, and provided with a non-transitory computer readable medium programmed to cause the semiconductor processing apparatus to execute a plurality of deposition cycles, the deposition cycle comprising: providing a boron halide precursor in vapor phase in the reaction chamber; providing a carbon-containing precursor in vapor phase in the reaction chamber; and providing a reactive species generated from a plasma produced from a reactant gas into the reaction chamber.
